(19) United States
(12) Patent Application Publication
(10) Pub. No.: US 2022/0377927 A1
(43) Pub. Date: Nov. 24, 2022

(54) SERVER CHASSIS AND SERVER

(71) Applicant: Fulian Precision Electronics (Tianjin) Co., LTD., Tianjin (CN)

(72) Inventors: HAN-YU LI, New Taipei (TW); WEN-HU LU, Tianjin (CN); LI-YI YIN, Tianjin (CN); SHU-TONG WANG, Tianjin (CN)

(21) Appl. No.: 17/568,048

(22) Filed: Jan. 4, 2022

(30) Foreign Application Priority Data
May 19, 2021 (CN) 202110548173.7

(51) Int. Cl. H05K 7/14; H05K 5/00; H05K 5/02

(52) U.S. Cl. CPC H05K 7/1489; H05K 7/1487; H05K 5/0021; H05K 5/0256

(57) ABSTRACT

A server chassis includes at least one first tray, at least one second tray, a housing, a first interface, the housing includes a bottom wall and a side wall, the bottom wall and the side wall surrounds and forms a receiving cavity with an opening. The first interface is located in the receiving cavity; the first interface is placed at a corner of the bottom wall close to the opening and the side wall. The first tray and the second tray are stacked in the receiving cavity, and the first tray is located below the second tray. The first tray slides out or retracts the receiving cavity through the opening. The second tray slides out or retracts the receiving cavity through the opening; the first tray and the second tray are configured to carry hard disks of a plurality of arrays. The present disclosure also provides a server.

### TECHNICAL FIELD

The present disclosure relates to server chassis and server.

### BACKGROUND

In the technical field of system structure design, 1 U usually refers to the height (units of thickness) of a rack server, 1 U=44.45 mm, 2 U is 88.9 mm. U (unit) is a unit representing the external size of the server. This detailing of size is determined by the American Electronics Industry Association as an industry group. The reason for specifying the size of the server is to keep the server in certain standard sizes so the server can be placed on the shell of the server chassis.

Usually, the server chassis has front and rear outlet interfaces at the front and rear ends. There are very particular requirements for the space utilization of 2 U servers. The traditional connection mode of front outlet and rear outlet no longer meets the layout of a computer room. For example, the traditional placement method of 42 3.5-inch hard disks is three-layer tray, 14 hard disks being arranged on each tray, but this method no longer meets the chassis length requirements when supporting front outgoing line or rear outgoing line, so there is a difficult problem of optimal space utilization.

Therefore, improvement is desired.

### BRIEF DESCRIPTION OF THE DRAWINGS

FIG. 1 is a schematic diagram of a server chassis according to an embodiment of the present disclosure.

FIG. 2 is a schematic diagram of a housing and a first tray of the chassis according to an embodiment of the present disclosure.

FIG. 3 is another schematic diagram of the server chassis of an embodiment of the present disclosure.

FIG. 4 is a schematic diagram of a second tray of the chassis in an embodiment of the present disclosure.

FIG. 5 is another schematic diagram of the server chassis of an embodiment of the present disclosure.

FIG. 6 is a schematic diagram of a server according to an embodiment of the present disclosure.

### DETAILED DESCRIPTION

The technical solutions in the embodiments of the present disclosure will be described in conjunction with the accompanying drawings in the embodiments of the present disclosure. Obviously, the described embodiments are part of the embodiments of the present disclosure, not all of them. Based on the embodiments of the present disclosure, all other embodiments obtained by those of ordinary skill in the art without creative work shall fall within the protection scope of the present disclosure.

The following disclosure provides many different embodiments or examples to implement different structures of the present application. In order to simplify the disclosure of the present application, the components and settings of specific examples are described below. Of course, they are merely examples and are not intended to limit the present application. In addition, the present application may repeat reference numbers and reference letters in different examples for the purpose of simplification and clarity, which itself does not indicate a relationship between the various embodiments and settings discussed.

The embodiments of the present disclosure provide a server chassis, the server chassis includes at least one first tray, at least one second tray, a housing, and a first interface. The housing includes a bottom wall and a side wall wherein the bottom wall and the side wall surround and form a receiving cavity with an opening, height of the housing is 2 U. The first interface is located in the receiving cavity; wherein the first interface is placed at a corner of the bottom wall close to the opening and the side wall. The first tray and the second tray are stacked in the receiving cavity, and the first tray is located below the second tray; wherein both sides of the first tray are slidably connected to the side wall, and the first tray can slide out of or retract into the receiving cavity through the opening; both sides of the second tray are slidably connected to the side wall, and the second tray slides or retracts through the opening; the first tray and the second tray are configured to carry pluralities of hard disks and arrays of hard disks.

The server chassis is arranged in parallel with the first interface through the first tray, and then the second tray is arranged on the upper layer of the first tray, so as to support the interface and carry as many hard disks as possible, so as to improve the space utilization rate.

The embodiment of the present disclosure provides a server, the server includes the server chassis. The construction and adaptability of server improves space utilization and interfaces to the exterior through the server chassis.

Some embodiments of the present disclosure are described in detail below in combination with the accompanying drawings.

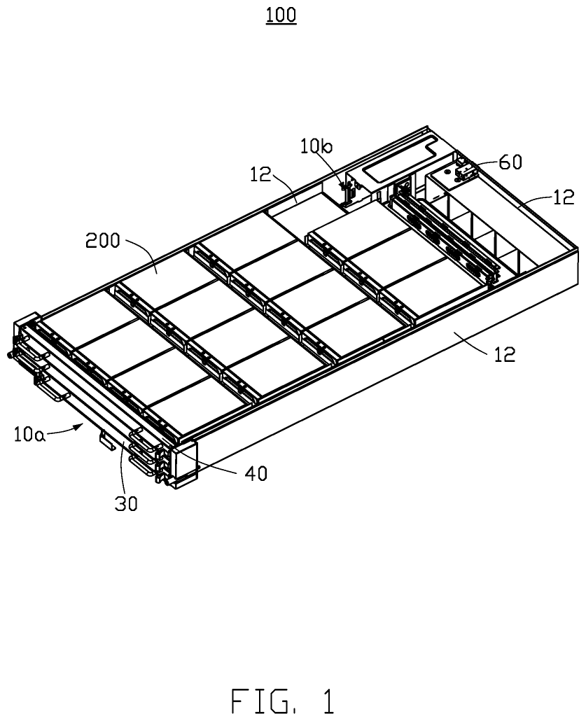

FIG. 1 illustrates a server chassis 100 in accordance with an embodiment of the present disclosure. The server chassis 100 is used to receive a plurality of hard disks 200.

The server chassis 100 includes a housing 10. The housing 10 includes a bottom wall 11 and a side wall 12. The bottom wall 11 can be rectangular. In one embodiment, the housing 10 can include three side walls 12, and the three side walls 12 have the same height, so that the bottom wall 11 and the three side walls 12 can surround and form a receiving cavity 10b with an opening 10a. The opening 10a is arranged towards the length direction of the bottom wall 11. The height of the side wall 12 is 2 U so that the height of the housing 10 is 2 U. It can be understood that the housing 10 also includes a top cover opposite to the bottom wall 11 to protect the housing 10.

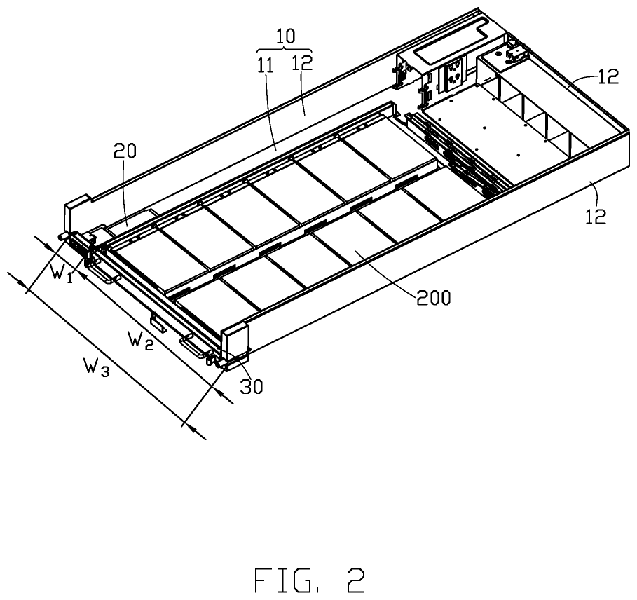

Referring to FIG. 2, the server chassis 100 further includes a first interface 20, the first interface 20 is located in the receiving cavity 10b and is placed at the corner of the bottom wall 11 close to the opening 10a and the side wall 12. One end of the first interface 20 extends out of the opening 10a for plug or wire insertion, and other end of the first interface 20 extends along the length direction of the bottom wall 11.

The server chassis 100 further includes at least one first tray 30, the first tray 30 is used to carry the hard disks 200 of arrays. The first tray 30 is located on the bottom wall 11, and the width W2 of the first tray 30 is equal to the difference between the width W3 of the bottom wall 11 and the width W1 of the first interface 20, so as to maximize the width of the first tray 30. Thus, it can carry hard disks 200 to its maximum capacity. Both sides of the first tray 30 are slidably connected to the side wall 12, and the first interface 20 can slide retract through the opening 10a for replacement or repair of the hard disks 200.

Referring to FIG. 1, the server chassis 100 further includes a second tray 40, the second tray 40 is used to carry the hard disks 200 of a plurality of arrays. The width of the second tray 40 is equal to the width of the bottom wall 11 to maximize the width of the second tray 40, so as to carry as many hard disks 200 as possible. Both sides of the second tray 40 are also slidably connected to the side wall 12, and the second tray 40 can slide or retract through the opening 10a for replacement or repair of the hard disks 200.

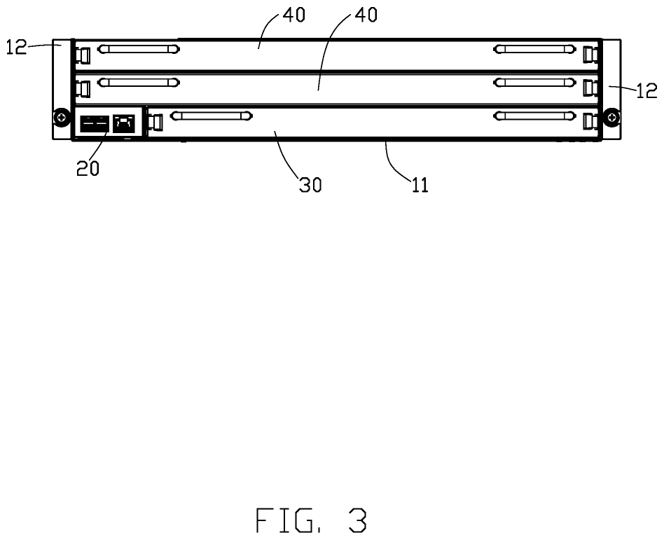

Referring to FIG. 3, in order to improve the space utilization, the first tray 30 and the second tray 40 are placed in the receiving cavity 10b in a laminated manner, the first interface 20 being located on the bottom wall 11. Therefore, the first tray 30 is located below the second tray 40, the first tray 30 is located on the bottom wall 11, and the second tray 40 is located above the first tray 30 and the first interface 20.

In some embodiments, the hard disks 200 have a standard size of 3.5 inches. The first tray 30 is provided with one hard disk 200 and the second tray 40 is provided with two. In other embodiment, the first tray 30 and the second tray 40 may also accept other quantities according to the size and thickness of the hard disk, but the difference between the total height of the first tray 30 and the height of the first interface 20 is less than the height of one first tray 30 to maximize the number of the hard disks 200. It can be understood that the first tray 30 and the first interface 20 can also be located on the second layer or the uppermost layer, while the second tray 40 is located on the other layers, that is, layers can be exchanged with each other.

In some embodiments, the height of the first tray 30 and the second tray 40 is the same, and the height of each of the first tray 30 and the second tray 40 is 27.2 mm.

Referring to FIG. 2, in some embodiments, the first tray 30 can carry hard disks 200 on the side wall 12. The size of the hard disks 200 is 3.5 inches, and the hard disks 200 are in a 2×6 array. In this array mode, the hard disks 200 are arranged in the width direction along the length direction of the first tray 30, and the hard disks 200 are arranged in the length direction along the width direction of the first tray 30.

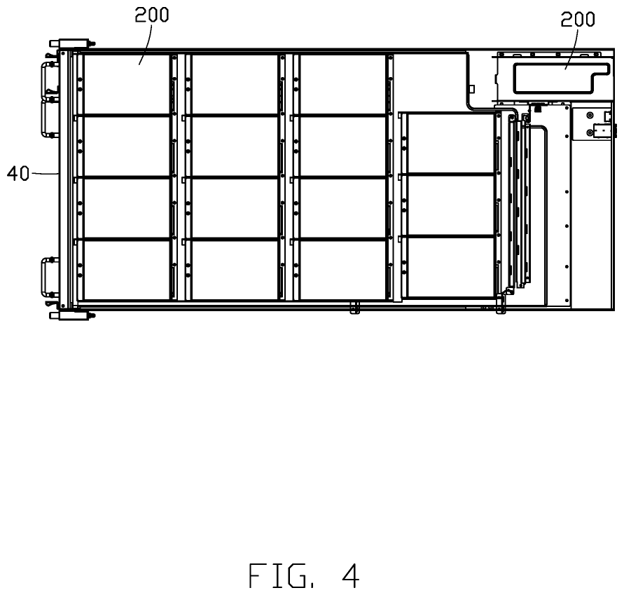

Referring to FIG. 4, in some embodiments, the second tray 40 can carry 15 hard disks 200. The size of such hard disk 200 is 3.5 inches, and the hard disk 200 is in a 4×4 array. In this array mode the hard disk 200 is arranged in the width direction of the first tray 30, and the hard disk 200 is arranged in the length direction of the first tray 30.

It should be noted that the corner near the inner side of the receiving cavity 10b and the side of the first interface 20 in the array is vacant. The vacancy is used to avoid the component, 16 hard disks 200 cannot be arrayed, and a hard disk 200 needs to be vacant near the component.

In some embodiments, the outer ends of the first tray 30 and the second tray 40 are provided with handles, to allow pulling of the first tray 30 and the second tray 40.

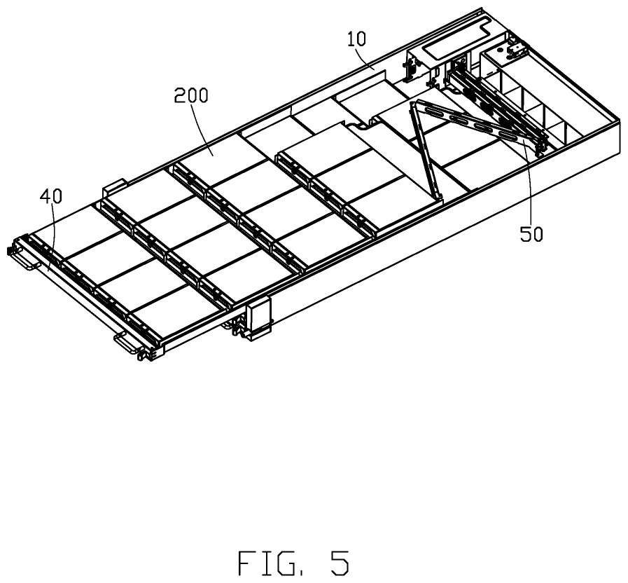

Referring to FIG. 5, in some embodiments, the inner ends of the first tray 30 and the second tray 40 are provided with a cable management mechanism 50, the cable management mechanism 50 sorts and holds the cables connected between the rear ends of the first tray 30 and the second tray 40 and the interior of the housing 10. As an exemplary example, the cable management mechanism 50 is a foldable connecting rod structure.

Referring to FIG. 1, the server chassis 100 further includes a second interface 60. The second interface 60 is located in the receiving cavity 10b and passes through the opposite side wall 12 of the opening 10a for plug or wire insertion.

It can be understood that in other embodiments, the first tray 30 and the second tray 40 can each carry other numbers of hard disks. The first tray 30 and the second tray 40 can also carry other electronic components.

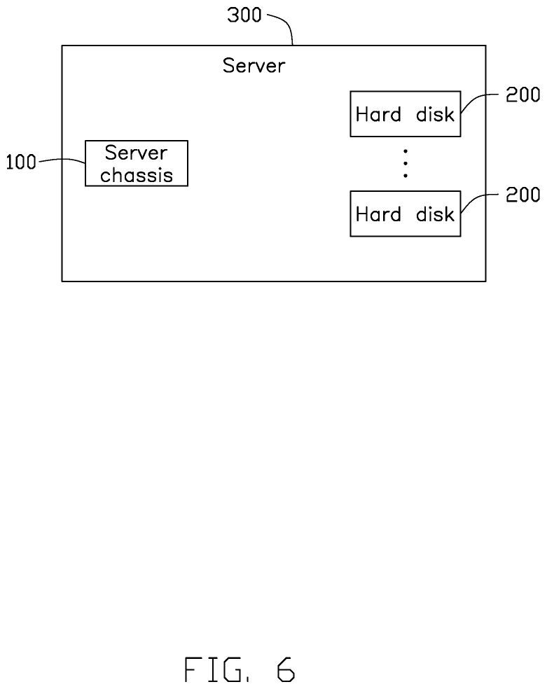

FIG. 6 illustrates a first tray 300 in accordance with an embodiment of the present disclosure.

The first tray 300 includes the server chassis 100 and a plurality of hard disks 200. The server chassis 100 is used to receive the plurality of the hard disks 200. It can be understood that the first tray 300 may also include other electronic components such as a motherboard.

The server chassis 100 is arranged in parallel with the first interface 20 through the first tray 30, and then the second tray 40 is arranged on the upper layer of the first tray 30 to support the interface and carry as many hard disks 200 as possible, so as to improve space utilization. The first tray 300 also achieves the purpose of better utilization of space and supports the outgoing interface through the server chassis 100.

Those of ordinary skill in the art should realize that the above embodiments are only used to illustrate the present disclosure, but not to limit the present disclosure. As long as they are within the essential spirit of the present disclosure, the above embodiments are appropriately made. Changes and changes fall within the scope of protection of the present disclosure.

What is claimed is:

1. A server chassis comprising:
at least one first tray;
at least one second tray;
a housing comprising a bottom wall and a side wall; wherein the bottom wall and the side wall surrounds and forms a receiving cavity with an opening, and height of the housing is 2 U; and
a first interface locating in the receiving cavity; wherein the first interface is placed at a corner of the bottom wall close to the opening and the side wall;
wherein width of the first tray is equal to difference between width of the bottom wall and width of the first interface, width of the second tray is equal to the width of the bottom wall; and
wherein the first tray and the second tray are stacked in the receiving cavity, and the first tray is located below the second tray; wherein both sides of the first tray are slidably connected to the side wall, and the first tray slides out or retracts the receiving cavity through the opening; both sides of the second tray are slidably connected to the side wall, and the second tray slides out or retracts the receiving cavity through the opening; the first tray and the second tray are configured to carry hard disks of a plurality of arrays.

2. The server chassis of claim 1, wherein:
difference between total height of the first trays and height of the first interface is less than height of one first trays.

3. The server chassis of claim 2, wherein:
the height of the first tray is the same as height of the second tray.

4. The server chassis of claim 3, wherein:
the server chassis comprises one first tray and two second trays.

5. The server chassis of claim 1, wherein:
difference between height of the housing and total height of the first trays and the second trays is less than height of one first tray or one second tray.

6. The server chassis of claim 1, wherein:
the first tray and the second tray are configured to carry 3.5-inch hard disk.

7. The server chassis of claim 1, wherein:
the first tray carries 12 hard disks, size of the hard disk is 3.5 inches, and makes the hard disks array in a form of 2×6.

8. The server chassis of claim 1, wherein:
the second tray carries 15 hard disks, size of the hard disk is 3.5 inches, and makes the hard disks array in a form of 4×4; a corner of the array close to an inner side of the receiving cavity and one side of the first interface are vacant to avoid components.

9. The server chassis of claim 1, wherein:
the server chassis further comprises a second interface, the second interface is disposed in the receiving cavity.

10. The server chassis of claim 9, wherein:
the second interface is disposed on the side wall opposite to the opening.

11. A server comprising:
a plurality of hard disks;
a server chassis comprising:
at least one first tray;
at least one second tray;
a housing comprising a bottom wall and a side wall; wherein the bottom wall and the side wall surrounds and forms a receiving cavity with an opening, and height of the housing is 2 U; and
a first interface locating in the receiving cavity; wherein the first interface is placed at a corner of the bottom wall close to the opening and the side wall;
wherein width of the first tray is equal to difference between width of the bottom wall and width of the first interface, width of the second tray is equal to the width of the bottom wall; and
wherein the first tray and the second tray are stacked in the receiving cavity, and the first tray is located below the second tray; wherein both sides of the first tray are slidably connected to the side wall, and the first tray slides out or retracts the receiving cavity through the opening; both sides of the second tray are slidably connected to the side wall, and the second tray slides out or retracts the receiving cavity through the opening; the first tray and the second tray are configured to carry the hard disks of a plurality of arrays.

12. The server of claim 11, wherein:
difference between total height of the first trays and height of the first interface is less than height of one first trays.

13. The server of claim 12, wherein:
the height of the first tray is the same as height of the second tray.

14. The server of claim 13, wherein:
the server chassis comprises one first tray and two second trays.

15. The server of claim 11, wherein:
difference between height of the housing and total height of the first trays and the second trays is less than height of one first tray or one second tray.

16. The server of claim 11, wherein:
the first tray and the second tray are configured to carry 3.5-inch hard disk.

17. The server of claim 11, wherein:
the first tray carries 12 hard disks, size of the hard disk is 3.5 inches, and makes the hard disks array in a form of 2×6.

18. The server of claim 11, wherein:
the second tray carries 15 hard disks, size of the hard disk is 3.5 inches, and makes the hard disks array in a form of 4×4; a corner of the array close to an inner side of the receiving cavity and one side of the first interface are vacant to avoid components.

19. The server of claim 11, wherein:
the server chassis further comprises a second interface, the second interface is disposed in the receiving cavity.

20. The server of claim 19, wherein:
the second interface is disposed on the side wall opposite to the opening.
